(19) United States
(12) Patent Application Publication
(10) Pub. No.: US 2026/0190658 A1
(43) Pub. Date: Jul. 2, 2026

(54) DISPLAY DEVICE, ELECTRONIC DEVICE, AND METHOD FOR MANUFACTURING A DISPLAY DEVICE

(71) Applicant: SAMSUNG DISPLAY CO., LTD., Yongin-Si (KR)

(72) Inventors: JINGYU KIM, Yongin-si (KR); JUNGYUN JO, Yongin-si (KR)

(21) Appl. No.: 19/279,011

(22) Filed: Jul. 24, 2025

(30) Foreign Application Priority Data
Dec. 26, 2024 (KR) 10-2024-0197699

(51) Int. Cl. H10K 59/124; H10K 59/12; H10K 59/123

(52) U.S. Cl. CPC H10K 59/124; H10K 59/1201; H10K 59/123

(57) ABSTRACT

A display device includes a substrate, a circuit layer including a plurality of transistors, and first and second light-emitting diodes. The first light-emitting diode overlaps a first light-emitting region and includes a first pixel electrode, a first light-emitting layer, and a common electrode. The second light-emitting diode overlaps a second light-emitting region and includes a second pixel electrode, a second light-emitting layer, and the common electrode. The first pixel electrode includes a first lower metal layer, a first inorganic layer, a first hard mask layer, and a first upper metal layer. The second pixel electrode includes a second lower metal layer, a second inorganic layer, a second hard mask layer, a third inorganic layer, and a second upper metal layer. The first inorganic layer and the second inorganic layer have substantially the same thickness, and the first pixel electrode and the second pixel electrode have different thicknesses.

### CROSS-REFERENCE TO RELATED APPLICATIONS

This application claims priority under 35 U.S.C. § 119 to Korean Patent Application No. 10-2024-0197699, filed on Dec. 26, 2024 in the Korean Intellectual Property Office, the disclosure of which is incorporated by reference in its entirety herein.

### 1. TECHNICAL FIELD

The present disclosure relates to a display device, an electronic device, and a method for manufacturing a display device. More specifically, the present disclosure pertains to a display device, an electronic device, and a method for manufacturing a display device that includes a hard mask to prevent damage to a lower metal layer during the etching process by differentiating the thickness of pixel electrodes to achieve different resonant distances for each pixel.

### 2. DISCUSSION OF RELATED ART

Generally, display devices are manufactured through multiple-step processes, which include an etching process to form thin film patterns.

Research is being conducted concerning methods that utilize some of the internal components of the display device as masks for patterning, instead of using external masks.

### SUMMARY

The present disclosure provides a display device with increased reliability and increased device efficiency.

The present disclosure also provides an electronic device with increased reliability and increased device efficiency.

Furthermore, the present disclosure aims to provide a method for manufacturing a display device with increased reliability and device efficiency.

According to an embodiment of the present disclosure, a display device includes a substrate having a plurality of light-emitting regions defined therein. A circuit layer is disposed on the substrate. The circuit layer comprises a plurality of transistors. A first light-emitting diode and a second light-emitting diode are disposed on the circuit layer. The first light-emitting diode overlaps a first light-emitting region among the plurality of light-emitting regions and comprises a first pixel electrode, a first light-emitting layer, and a common electrode. The second light-emitting diode overlaps a second light-emitting region among the plurality of light-emitting regions and comprises a second pixel electrode, a second light-emitting layer, and the common electrode. The first pixel electrode comprises, in sequential stacking order, a first lower metal layer, a first inorganic layer, a first hard mask layer, and a first upper metal layer and has a first contact hole defined therein, the first contact hole penetrating through the first inorganic layer and the first hard mask layer. The second pixel electrode comprises, in sequential stacking order, a second lower metal layer, a second inorganic layer, a second hard mask layer, a third inorganic layer, and a second upper metal layer and has a second contact hole defined therein. The second contact hole penetrates through the second inorganic layer, the second hard mask layer, and the third inorganic layer. The first inorganic layer and the second inorganic layer have substantially a same thickness as each other in a vertical direction. The first pixel electrode and the second pixel electrode have different thicknesses from each other in the vertical direction.

In an embodiment, the thickness of the second pixel electrode in the vertical direction may be greater than the thickness of the first pixel electrode in the vertical direction.

In an embodiment, the first and second hard mask layers may have substantially the same thickness as each other in the vertical direction.

In an embodiment, the first and second hard mask layers may each have an etching selectivity different from that of the third inorganic layer.

In an embodiment, the second contact hole may include: a first sub-contact hole penetrating the second inorganic layer and the second hard mask layer; and a second sub-contact hole penetrating the third inorganic layer. The first contact hole and the first sub-contact hole may have substantially the same depth as each other.

According to an embodiment, the display device may further include a third light-emitting diode disposed on the circuit layer. The third light-emitting diode may overlap a third light-emitting region among the plurality of light-emitting regions and may include a third pixel electrode, a third light-emitting layer, and the common electrode. The third pixel electrode may include, in sequential stacking order, a third lower metal layer, a fourth inorganic layer, a third hard mask layer, a fifth inorganic layer, a sixth inorganic layer, and a third upper metal layer. The third pixel electrode includes a third contact hole penetrating through the fourth inorganic layer, the third hard mask layer, the fifth inorganic layer, and the sixth inorganic layer may be defined. The fourth inorganic layer may have substantially the same thickness as the first and second inorganic layers in the vertical direction.

In an embodiment, the first, second, and third hard mask layers may have substantially the same thickness as each other in the vertical direction.

In an embodiment, the second contact hole includes a first sub-contact hole penetrating through the second inorganic layer and the second hard mask layer. A second sub-contact hole penetrates through the third inorganic layer. The third contact hole may include: a third sub-contact hole penetrating the fourth inorganic layer and the third hard mask layer; and a fourth sub-contact hole penetrating the fifth and sixth inorganic layers. The third sub-contact hole, the first contact hole, and the first sub-contact hole may have substantially the same depth as each other.

In an embodiment, the first lower metal layer may be spaced apart from the first contact hole, and the second lower metal layer may be spaced apart from the second contact hole. The first upper metal layer may be electrically connected to a corresponding transistor among the transistors through the first contact hole. The second upper metal layer may be electrically connected to a corresponding transistor among the transistors through the second contact hole.

According to an embodiment, the display device may further include a pixel defining layer disposed between the first and second pixel electrodes. The pixel defining layer may be in direct contact with the first and second inorganic layers.

According to an embodiment, the first and second hard mask layers may include amorphous carbon (a-C).

According to an embodiment, the third inorganic layer may include silicon oxide (SiOx).

According to an embodiment of the present disclosure, a method for manufacturing a display device includes preparing a preliminary display panel by forming a circuit layer on a substrate. A plurality of lower metal layers is formed and is spaced apart from each other on the circuit layer. An intermediate layer is formed by: forming a first intermediate inorganic layer and a first intermediate hard mask layer on a first lower metal layer among the plurality of lower metal layers; and forming a second intermediate inorganic layer, a second intermediate hard mask layer, and a third intermediate inorganic layer on a second lower metal layer among the plurality of lower metal layers. A first etching is performed to form a first upper contact hole penetrating through the third intermediate inorganic layer. A second etching is performed to form a first lower contact hole penetrating through the first intermediate hard mask layer and the first intermediate inorganic layer and form a second lower contact hole penetrating through the second intermediate hard mask layer and the second intermediate inorganic layer and overlapping the first upper contact hole in a plan view. Upper metal layers are formed corresponding, respectively, to the plurality of lower metal layers. In the step of preparing the preliminary display panel, a circuit layer may be formed on a substrate. In the step of forming the lower metal layers, a plurality of lower metal layers spaced apart from each other may be formed on the circuit layer.

In an embodiment, in the step of forming the intermediate layer, a fourth intermediate inorganic layer, a third intermediate hard mask layer, a fifth intermediate inorganic layer, and a sixth intermediate inorganic layer may be further formed on a third lower metal layer among the lower metal layers. In the step of performing the first etching process, a second upper contact hole penetrating the sixth intermediate inorganic layer and a third upper contact hole penetrating the fifth intermediate inorganic layer may be further formed. In the step of performing the second etching process, a third lower contact hole penetrating the third intermediate hard mask layer may be further formed.

In an embodiment, the first through third intermediate hard mask layers may have an etching selectivity different from that of the third intermediate inorganic layer and may include amorphous carbon (a-C).

In an embodiment, the third inorganic layer may include silicon oxide (SiOx).

According to an embodiment of the present disclosure, a display device includes a substrate. A circuit layer is disposed on the substrate. The circuit layer comprises a plurality of transistors. A first light-emitting diode and a second light-emitting diode are disposed on the circuit layer. The first light-emitting diode comprises a first pixel electrode, a first light-emitting layer, and a common electrode. The second light-emitting diode comprises a second pixel electrode, a second light-emitting layer, and the common electrode. The first pixel electrode comprises, in sequential stacking order, a first lower metal layer, a first lower inorganic layer, a first upper inorganic layer, a first hard mask layer, and a first upper metal layer. A first lower contact hole is defined that penetrates through the first lower inorganic layer and the first upper inorganic layer. A first upper contact hole penetrating through the first hard mask layer is defined. The first lower contact hole and the first upper contact hole overlap in a plan view. The second pixel electrode comprises, in sequential stacking order, a second lower metal layer, a second lower inorganic layer, a second upper inorganic layer, a second hard mask layer, and a second upper metal layer. A second lower contact hole is defined penetrating through the second lower inorganic layer and the second upper inorganic layer. A second upper contact hole penetrating through the second hard mask layer is defined. The second lower contact hole and the second upper contact hole overlap in a plan view. The first lower inorganic layer and the second lower inorganic layer have substantially a same thickness as each other in a vertical direction. The first hard mask layer and the second hard mask layer have substantially a same thickness as each other in the vertical direction. The first upper inorganic layer and the second upper inorganic layer have different thicknesses from each other in the vertical direction. The first pixel electrode and the second pixel electrode have different thicknesses from each other in the vertical direction.

In an embodiment, the first and second hard mask layers may each include amorphous carbon (a-C).

In an embodiment, the first upper inorganic layer and the second upper inorganic layer may each include silicon oxide (SiOx).

In an embodiment, the first and second hard mask layers may have substantially a same thickness as each other in the vertical direction.

In an embodiment, the first and second hard mask layers may have substantially the same etching selectivity as each other. The first hard mask layer may have an etching selectivity different from that of each of the first upper inorganic layer and the second upper inorganic layer.

In an embodiment, the first lower contact hole and the second lower contact hole may have substantially the same depth as each other, while the first upper contact hole and the second upper contact hole may have different depths from each other.

According to an embodiment of the present disclosure, an electronic device includes a processor controlling a display device. A memory stores data required for operating the display device or the processor. A power conversion module generates or supplies power. The display device comprises a substrate having a plurality of light-emitting regions defined therein. A circuit layer is disposed on the substrate. The circuit layer comprises a plurality of transistors. A first light-emitting diode and a second light-emitting diode are disposed on the circuit layer. The first light-emitting diode overlaps a first light-emitting region among the plurality of light-emitting regions and comprises a first pixel electrode, a first light-emitting layer, and a common electrode. The second light-emitting diode overlaps a second light-emitting region among the plurality of light-emitting regions and comprises a second pixel electrode, a second light-emitting layer, and the common electrode. The first pixel electrode comprises, in sequential stacking order, a first lower metal layer, a first inorganic layer, a first hard mask layer, and a first upper metal layer and has a first contact hole defined therein. The first contact hole penetrates through the first inorganic layer and the first hard mask layer. The second pixel electrode comprises, in sequential stacking order, a second lower metal layer, a second inorganic layer, a second hard mask layer, a third inorganic layer, and a second upper metal layer and has a second contact hole defined therein. The second contact hole penetrates through the second inorganic layer, the second hard mask layer, and the third inorganic layer. The first inorganic layer and the second inorganic layer have substantially a same thickness as each other in a vertical direction. The first pixel electrode and the second pixel electrode have different thicknesses from each other in the vertical direction.

According to an embodiment of the present disclosure, it is possible to provide a display device, an electronic device, and a method for manufacturing a display device with increased reliability of the display device and increased device efficiency, by forming contact holes with the same depth for each pixel during the etching process and varying the thickness of the pixel electrodes for each pixel.

### BRIEF DESCRIPTION OF THE DRAWINGS

These and/or other features will become apparent and more readily appreciated from the following description of non-limiting embodiments, taken in conjunction with the accompanying drawings in which:

FIG. 1 is a plan view schematically illustrating a display device according to an embodiment of the present disclosure;

FIG. 2 is a cross-sectional view exemplarily illustrating a display device according to an embodiment of the present disclosure;

FIG. 3 is an enlarged view of region AA in FIG. 2 according to an embodiment of the present disclosure;

FIG. 4 is a cross-sectional view illustrating a portion of the display device according to an embodiment of the present disclosure;

FIG. 5 is a cross-sectional view illustrating another portion of the display device according to an embodiment of the present disclosure;

FIG. 6 is a cross-sectional view illustrating yet another portion of the display device according to an embodiment of the present disclosure;

FIG. 7 is a flow diagram illustrating a method for manufacturing a display device according to an embodiment of the present disclosure;

FIG. 8 is a flow diagram illustrating a particular step of the method for manufacturing a display device according to an embodiment of the present disclosure;

FIGS. 9A to 9N are schematic views illustrating the steps of the method for manufacturing a display device according to embodiments of the present disclosure;

FIG. 10 is a block diagram of an electronic device according to an embodiment of the present disclosure; and

FIGS. 11 to 13 are schematic views of electronic devices according to various embodiments of the present disclosure.

### DETAILED DESCRIPTION OF EMBODIMENTS

References will now be made in detail to certain non-limiting embodiments, of which examples are illustrated in the accompanying drawings, where like reference numerals refer to like elements throughout. Embodiments of the present disclosure may have a variety of forms and permutations, and the present disclosure shall by no means be construed as being limited to the described embodiments. Rather, embodiments of the present disclosure shall be construed to encompass all forms, permutations, equivalents and substitutes covered by the technical ideas and scope of the present disclosure. Accordingly, non-limiting embodiments are merely described below, by referring to the figures, to explain features of the present disclosure.

When an element (or region, layer, portion, etc.) is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. On the other hand, if one element is described to be “directly disposed on,” “directly placed on,” “directly arranged on,” “directly connected to,” or “directly coupled to” another element, it shall be construed that there is no other element interposed therebetween.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not necessarily be limited to the thicknesses, ratios, dimensions, etc. illustrated in the drawings.

Terms such as “first” and “second” may be used in describing various elements, but the above elements shall not be restricted to the above terms. The above terms may be used only to distinguish one element from the other. For instance, the first element may be named the second element, and vice versa, without departing the scope of claims of the present disclosure. Unless clearly used otherwise, any expressions in a singular form may include a meaning of a plural form. The term “and/or” shall include the combination of a plurality of listed items or any of the plurality of listed items.

Moreover, relative terms, such as “below,” “under,” “beneath,” “lower,” “bottom,” “above,” “over,” “upper,” “top,” etc., may be used herein to describe one element's relationship to another element as illustrated in the accompanying figures. It shall be understood that relative terms are intended to encompass different orientations of the device in addition to the orientation depicted in the accompanying figures. For example, if the device in one of the figures is turned over, elements described as being on the “lower” side of the other elements would then be oriented on “upper” sides of the other elements. The term “lower” can therefore encompass an orientation of both “lower” and “upper,” depending on the particular orientation of the figure. Similarly, if the device in one of the figures is turned over, elements described as “below” or “beneath” other elements would then be oriented “above” the other elements. The term “below” or “beneath” can therefore encompass an orientation of both above and below.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

In the present specification, when a particular process sequence may be implemented differently, the described sequence of processes may be performed in a different order. For example, two sequentially described processes may be performed substantially simultaneously, or the order of description may be reversed.

The present disclosure concerns a display device having pixel electrodes including contact holes defined therein. The pixel electrodes in different light-emitting regions may have different thicknesses from each other in the vertical direction by varying the number of inorganic layers included in the stacked structure of each of the pixel electrodes. The thicknesses of the pixel electrodes may be varied to allow the light emitted by the corresponding light-emitting diodes to resonate to increase the efficiency of the display device.

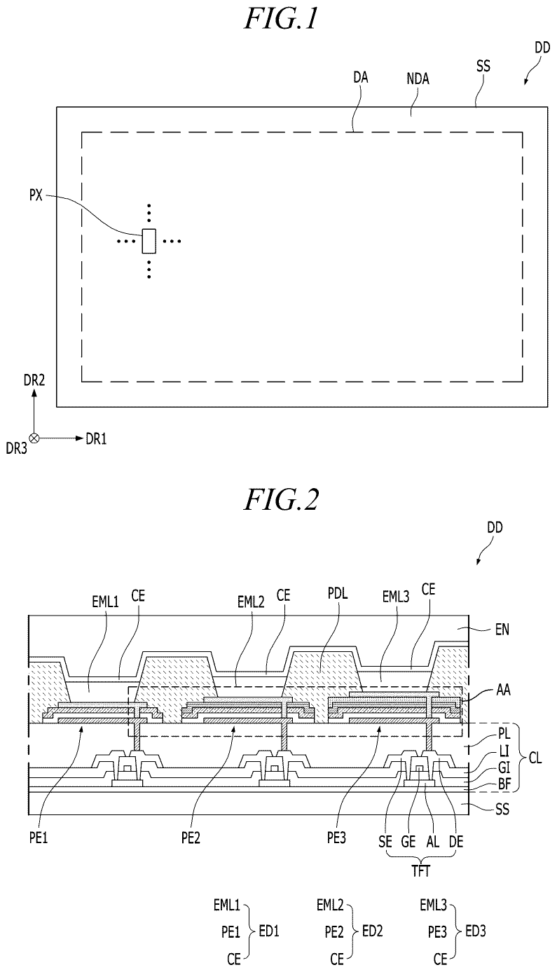

Additionally, in a method of manufacturing the display device, contact holes having the same depth as each other may be formed by arranging a single hard mask layer on inorganic layers having the same thickness as each other for each of the plurality of pixel electrodes. This process prevents damage to the lower metal layers and increases the reliability of the display device. FIG. 1 is a plan view schematically illustrating a display device according to an embodiment of the present disclosure. Referring to FIG. 1, a display device DD may have a display area DA and a non-display area NDA defined therein. In an embodiment, the non-display area NDA may at least partially surround the display area DA (e.g., in a plan view). The display device DD may include a substrate SS, and the display area DA and the non-display area NDA may be defined as regions on the substrate SS. The substrate SS may have a plurality of light-emitting regions defined therein.

The display area DA is a region where images are displayed, and a plurality of pixels may be arranged therein. In an embodiment, the display area DA may have various shapes, such as circular, elliptical, polygonal, or other specific geometric shapes (e.g., in a plan view).

A plurality of pixels PX, each including light-emitting diodes, such as organic light-emitting diodes, overlapping light-emitting regions, respectively, may be disposed in the display area DA of the substrate SS. Each pixel PX may include a transistor configured to control the light-emitting diodes. A single pixel PX may include at least one or more transistors.

In a peripheral area PA of the substrate SS, various wirings configured to deliver electrical signals applied to the display area DA may be arranged. In an embodiment, a transistor may be disposed in the non-display area NDA, and the transistor may be a part of a circuit unit configured for controlling electrical signals applied to the display area DA.

Hereinafter, an organic light-emitting display device will be described as an example of the display device DD according to an embodiment of the present disclosure. However, the display device of the present disclosure is not necessarily limited thereto. In some embodiments, the display device DD may be an inorganic light-emitting display device or a quantum dot light-emitting display device. For example, a light-emitting layer of the light-emitting diode provided in the display device DD may include organic materials, inorganic materials, quantum dots, a combination of organic materials and quantum dots, or a combination of inorganic materials and quantum dots.

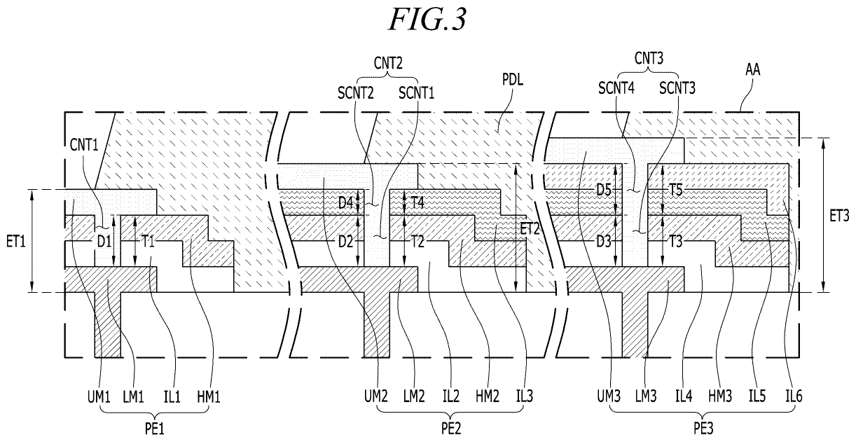

FIG. 2 is a cross-sectional view illustrating a display device according to an embodiment of the present disclosure. FIG. 3 is an enlarged view of region AA in FIG. 2. Referring to FIGS. 2 and 3, a display device DD according to an embodiment of the present disclosure may include a substrate SS, a circuit layer CL, first to third light-emitting diodes ED1, ED2, ED3 overlapping first to third light-emitting regions, respectively, a pixel defining layer PDL, and an encapsulation layer EN.

The substrate SS may be made of various materials, such as glass, metal, or plastic. In an embodiment, the substrate SS may be a flexible substrate. For example, the substrate SS may include polymer resins such as polyethersulfone (PES), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), or cellulose acetate propionate (CAP).

The circuit layer CL may be disposed on the substrate SS (e.g., disposed directly thereon in the third direction DR3) and may include a transistor TFT, a gate insulating layer GI, an interlayer insulating layer LI, and a planarization layer PL.

The transistor TFT may include an active layer AL, a gate electrode GE, a source electrode SE, and a drain electrode DE. A gate insulating layer GI may be disposed between the gate electrode GE and the active layer AL (e.g., in the third direction DR3) to provide electrical insulation between the gate electrode GE and the active layer AL.

The active layer AL may be disposed on a buffer layer BF (e.g., disposed directly thereon in the third direction DR3) and may be formed of an inorganic semiconductor such as amorphous silicon or polysilicon, or an organic semiconductor. In some embodiments, the active layer AL may be formed of an oxide semiconductor, such as an oxide of elements selected from groups 12, 13, and 14 of the periodic table, including zinc (Zn), indium (In), gallium (Ga), tin (Sn), cadmium (Cd), germanium (Ge), or hafnium (Hf), or combinations thereof.

The gate insulating layer GI may be disposed on (e.g., disposed directly thereon) the buffer layer BF and cover the active layer AL. The gate electrode GE may be disposed on the gate insulating layer GI (e.g., disposed directly thereon in the third direction DR3).

The interlayer insulating layer LI may be disposed on (e.g., disposed directly thereon) the gate insulating layer GI and the gate electrode GE, covering the gate electrode GE. In an embodiment, the source electrode SE and the drain electrode DE may be formed on the interlayer insulating layer LI and may be in direct contact with the active layer AL through contact holes.

The structure of the transistor TFT is not necessarily limited to the described example and may adopt various configurations. For example, in some embodiments the transistor TFT may have a top-gate structure or a bottom-gate structure where the gate electrode GE is disposed beneath the active layer AL.

The planarization layer PL may be disposed on (e.g., disposed directly thereon) the source electrode SE, the drain electrode DE, and the interlayer insulating layer LI. The first to third light-emitting diodes ED1, ED2, ED3 may be disposed on the planarization layer PL. The planarization layer PL may provide a relatively flat upper surface to allow the first to third pixel electrodes PE1, PE2, PE3 to be formed relatively flat. The planarization layer PL may be formed of an organic or inorganic material as a single or multi-layer film.

In an embodiment, the planarization layer PL may include materials such as benzocyclobutene (BCB), polyimide, hexamethyldisiloxane (HMDSO), polymethylmethacrylate (PMMA), polystyrene (PS), or polymer derivatives with phenolic groups, as well as acryl-based, imide-based, aryl ether-based, amide-based, fluorine-based, p-xylene-based, vinyl alcohol-based polymers, and their blends. Alternatively, the planarization layer PL may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO₂). After forming the planarization layer PL, chemical and/or mechanical polishing may be performed to achieve the relatively flat upper surface.

In an embodiment, the planarization layer PL may include openings exposing either the source electrode SE or the drain electrode DE of the transistor TFT, and the pixel electrodes PE1, PE2, PE3 may be electrically connected to the transistor TFT by directly contacting the source electrode SE or the drain electrode DE through the openings.

The display device according to an embodiment may further include a buffer layer BF disposed between the active layer AL and the substrate SS (e.g., in the third direction DR3. The buffer layer BF may be configured to prevent the diffusion of impurity ions from the upper surface of the substrate SS, inhibit moisture or external air penetration, and planarize the surface. In some embodiments, the buffer layer BF may be formed of inorganic materials such as silicon oxide, silicon nitride, silicon oxynitride, aluminum oxide, aluminum nitride, titanium oxide, or titanium nitride, or organic materials such as polyimide, polyester, or acryl, or a laminated structure thereof.

The first to third light-emitting diodes ED1, ED2, ED3 may be disposed on the planarization layer PL and may overlap first to third light-emitting regions, respectively. Each of the first to third light-emitting diodes ED1, ED2, ED3 may include a pixel electrode PE1, PE2, PE3, a light-emitting layer EML1, EML2, EML3, and a common electrode CE.

In an embodiment, the light-emitting layers EML1, EML2, EML3 may include organic materials containing fluorescent or phosphorescent substances that emit red, green, blue, or white light. The light-emitting layers EML1, EML2, EML3 may be made of low-molecular-weight organic materials or high-molecular-weight organic materials. In an embodiment, further disposed beneath the light-emitting layers EML1, EML2, EML3 may be functional layers such as a hole transport layer and a hole injection layer. The light-emitting layer EML1, EML2, EML3 may be disposed corresponding, respectively, to the first to third pixel electrodes PE1, PE2, PE3.

The first to third light-emitting diodes ED1, ED2, ED3 may be configured to emit light in different wavelength bands. For example, in an embodiment the first light-emitting diode ED1 may be configured to emit light in the wavelength band corresponding to red, the second light-emitting diode ED2 may be configured to emit light in the wavelength band corresponding to green, and the third light-emitting diode ED3 may be configured to emit light in the wavelength band corresponding to blue. However, embodiments of the present disclosure are not necessarily limited thereto, and any two of the light-emitting diodes ED1, ED2, ED3 may be configured to emit light in the same wavelength band. In some embodiments, a fourth light-emitting diode may be included to emit light in a wavelength band different from those of the first to third light-emitting diodes ED1, ED2, ED3.

The common electrode CE may be a transparent or semi-transparent electrode. The common electrode CE may be disposed across both the display area DA and the non-display area NDA and positioned above the light-emitting layers EML1, EML2, EML3 and the pixel defining layer PDL. In an embodiment, the common electrode CE may be integrally formed (e.g., commonly disposed) to correspond to the first to third pixel electrodes PE1, PE2, PE3.

In an embodiment, the common electrode CE may include at least one material selected from Ag, Mg, Cu, Al, Pt, Pd, Au, Ni, Nd, Ir, Cr, Li, Ca, LiF, Mo, Ti, W, In, Sn, and Zn, or compounds, mixtures, or oxides of at least two of these materials.

Detailed descriptions of the first to third pixel electrodes PE1, PE2, PE3, and the first to third light-emitting diodes ED1, ED2, ED3 will be provided below.

A pixel defining layer PDL may be disposed on (e.g., disposed directly thereon) the pixel electrodes PE1, PE2, PE3 and the planarization layer PL. The pixel defining layer PDL may serve to define pixels overlapping the light-emitting regions by having openings OP corresponding, respectively, to the pixels. Additionally, the pixel defining layer PDL may be configured to prevent arcing between the edges of the pixel electrodes PE1, PE2, PE3 and the common electrode CE by increasing the distance between the edges of the pixel electrodes PE1, PE2, PE3 and the common electrode CE. In an embodiment, the pixel defining layer PDL may be formed of organic materials such as polyimide or hexamethyldisiloxane (HMDSO).

The encapsulation layer EN may be disposed on the common electrode CE (e.g., disposed directly thereon in the third direction DR3). The encapsulation layer EN may include at least one inorganic encapsulation layer and at least one organic encapsulation layer. The encapsulation layer EN may be configured to protect the components disposed beneath the encapsulation layer EN from external moisture or contaminants.

In an embodiment, the first light-emitting diode ED1 may include the first pixel electrode PE1, the first light-emitting layer EML1, and the common electrode CE. The first light-emitting diode ED1 may overlap a first light-emitting region. The second light-emitting diode ED2 may include the second pixel electrode PE2, the second light-emitting layer EML2, and the common electrode CE. The second light-emitting diode ED2 may overlap a second light-emitting region. The third light-emitting diode ED3 may include the third pixel electrode PE3, the third light-emitting layer EML3, and the common electrode CE. The third light-emitting diode ED3 may overlap a third light-emitting region.

In an embodiment, the first pixel electrode PE1 may include, in sequential stacking order, a first lower metal layer LM1, a first inorganic layer IL1, a first hard mask layer HM1, and a first upper metal layer UM1.

The first lower metal layer LM1 may be disposed on the circuit layer CL (e.g., disposed directly thereon in the third direction DR3). In an embodiment, the first lower metal layer LM1 may be a reflective layer including Ag, Mg, Al, Pt, Pd, Au, Ni, Nd, Ir, Cr, or compounds thereof.

The first inorganic layer IL1 may be disposed on (e.g., disposed directly thereon) the first lower metal layer LM1 and may have insulating properties. In an embodiment, the first inorganic layer IL1 may include inorganic materials. In an embodiment, the first inorganic layer IL1 may include silicon oxide (SiOx).

In an embodiment of the present disclosure, the thickness of the first inorganic layer IL1 (e.g., in the third direction DR3 which is a vertical direction) may be adjusted in correspondence with the thickness of the first pixel electrode PE1 (e.g., in the third direction DR3). A detailed description of this will be provided later.

The first hard mask layer HM1 may be disposed on (e.g., disposed directly thereon) the first inorganic layer IL1. A first contact hole CNT1 penetrating through the first hard mask layer HM1 and the first inorganic layer IL1 may be defined in the first hard mask layer HM1 and the first inorganic layer IL1.

In an embodiment, the first to third hard mask layers HM1, HM2, HM3 may include amorphous carbon (a-C).

In an embodiment of the present disclosure, the first hard mask layer HM1 may have an etching selectivity different from that of a third inorganic layer IL3, which will be described later. In the context of the present disclosure, having a different etching selectivity means that the degree of etching of the two components may differ significantly from each other under a same etching process. For example, as the first hard mask layer HM1 has a different etching selectivity from the third inorganic layer IL3, the first hard mask layer HM1 may not be substantially etched or may be etched to a significantly lesser extent during the etching process for forming the third inorganic layer IL3, thereby protecting the components disposed underneath the first hard mask layer HM1.

In an embodiment of the present disclosure, the first to third hard mask layers HM1, HM2, HM3 may have substantially the same etching selectivity as each other and may protect the components disposed beneath each of the first to third hard mask layers HM1, HM2, HM3 during the etching processes for forming the third inorganic layer IL3, the fifth inorganic layer IL5, and the sixth inorganic layer IL6.

The first upper metal layer UM1 may be disposed on the first hard mask layer HM1 (e.g., disposed directly thereon in the third direction DR3) and may be electrically connected to the first lower metal layer LM1 through the first contact hole CNT1. However, the configuration is not necessarily limited to this, and in some embodiments, the first upper metal layer UM1 may be insulated from the first lower metal layer LM1 and directly connected to the transistor TFT (see FIG. 2).

In an embodiment, the first upper metal layer UM1 may be a transparent or semi-transparent electrode and may be formed of a metal thin film including Yb, Li, Ca, LiF/Ca, LiF/Al, Al, Ag, Mg, or compounds thereof. Additionally, a transparent conductive oxide (TCO) layer, such as ITO, IZO, ZnO, or In2O3, may be further disposed on the metal thin film.

In an embodiment, the second pixel electrode PE2 may include, in sequential stacking order, a second lower metal layer LM2, a second inorganic layer IL2, a second hard mask layer HM2, a third inorganic layer IL3, and a second upper metal layer UM2.

Any redundant descriptions for substantially identical components will be omitted hereinafter. The second inorganic layer IL2 may be disposed between (e.g., directly therebetween) the second lower metal layer LM2 and the second hard mask layer HM2, while the third inorganic layer IL3 may be disposed between (e.g., directly therebetween) the second hard mask layer HM2 and the second upper metal layer UM2. The third inorganic layer IL3 may be configured to adjust the thickness of the second pixel electrode PE2 (e.g., in the third direction DR3) along with the second inorganic layer IL2.

In an embodiment of the present disclosure, the second inorganic layer IL2 may be formed in substantially the same process step as the first inorganic layer IL1. As will be described later, in an embodiment the first inorganic layer IL1 and the second inorganic layer IL2 may each be formed by partially removing a preliminary inorganic layer.

A second contact hole CNT2 may be defined in the second pixel electrode PE2. In an embodiment, the second upper metal layer UM2 may be electrically connected to the second lower metal layer LM2 through the second contact hole CNT2. However, the configuration is not necessarily limited to this, and in some embodiments the second upper metal layer UM2 may be electrically insulated from the second lower metal layer LM2 and directly connected to the transistor TFT (see FIG. 2).

In an embodiment, the second contact hole CNT2 may include a first sub-contact hole SCNT1 and a second sub-contact hole SCNT2. The first sub-contact hole SCNT1 may penetrate through the second inorganic layer IL2 and the second hard mask layer HM2, while the second sub-contact hole SCNT2 may penetrate through the third inorganic layer IL3. The first sub-contact hole SCNT1 and the second sub-contact hole SCNT2 may overlap each other in a plan view.

In an embodiment, the first pixel electrode PE1 may include a single inorganic layer, such as the first inorganic layer IL1, while the second pixel electrode PE2 may include two inorganic layers, such as the first and second inorganic layers IL2, IL3. The thicknesses of the first inorganic layer IL1 and the second inorganic layer IL2 (e.g., in the third direction DR3 which is a vertical direction) may be substantially the same as each other, and the thicknesses of the first hard mask layer HM1 and the second hard mask layer HM2 may also be substantially the same as each other (e.g., in the third direction DR3 which is a vertical direction). For example, a first thickness T1 may be substantially the same as a second thickness T2.

In an embodiment, the depth D1 of the first contact hole CNT1 and the depth D2 of the first sub-contact hole SCNT1 (e.g., in the third direction DR3) may be substantially the same as each other.

In an embodiment, the thickness ET1 of the first pixel electrode PE1 (e.g., in the third direction DR3) may be different from the thickness ET2 of the second pixel electrode PE2 (e.g., in the third direction DR3). The thickness ET2 of the second pixel electrode PE2 may be greater than the thickness ET1 of the first pixel electrode PE1.

In an embodiment of the present disclosure, the thickness ET1 of the first pixel electrode PE1 and the thickness ET2 of the second pixel electrode PE2 may be different from each other.

In an embodiment of the present disclosure, the wavelength of light emitted by the first light-emitting diode ED1 and the wavelength of light emitted by the second light-emitting diode ED2 may be different from each other. The thickness ET1 of the first pixel electrode PE1 for allowing the light emitted by the first light-emitting diode ED1 to resonate may be different from the thickness ET2 of the second pixel electrode PE2 for allowing the light emitted by the second light-emitting diode ED2 to resonate. In an embodiment of the present disclosure, the first thickness ET1 may be adjusted to allow the light emitted by the first light-emitting diode ED1 to resonate, and the second thickness ET2 may be adjusted to allow the light emitted by the second light-emitting diode ED2 to resonate.

In an embodiment, the third pixel electrode PE3 may include, in sequential stacking order, a third lower metal layer LM3, a fourth inorganic layer IL4, a third hard mask layer HM3, a fifth inorganic layer IL5, a sixth inorganic layer IL6, and a third upper metal layer UM3.

In an embodiment of the present disclosure, the fourth inorganic layer IL4 may be formed in substantially the same process step as the first inorganic layer IL1 and the second inorganic layer IL2. Similarly, the fifth inorganic layer IL5 may be formed in substantially the same process step as the third inorganic layer IL3.

In an embodiment, a third contact hole CNT3 may include a third sub-contact hole SCNT3 and a fourth sub-contact hole SCNT4. The third sub-contact hole SCNT3 may penetrate through the fourth inorganic layer IL4 and the third hard mask layer HM3, while the fourth sub-contact hole SCNT4 may penetrate through the fifth inorganic layer IL5 and the sixth inorganic layer IL6. The third sub-contact hole SCNT3 and the fourth sub-contact hole SCNT4 may overlap each other in a plan view.

In an embodiment, the first pixel electrode PE1 may include a single inorganic layer, such as the first inorganic layer IL1, the second pixel electrode PE2 may include two layers, such as the second and third inorganic layers IL2, IL3, and the third pixel electrode PE3 may include three inorganic layers, such as the fourth to sixth inorganic layers IL4, IL5, IL6. The fourth to sixth inorganic layers IL4, IL5, IL6 may be configured to adjust the thickness of the third pixel electrode PE3.

The wavelengths of light emitted by the first light-emitting diode ED1, the second light-emitting diode ED2, and the third light-emitting diode ED3 may be different from each other. The thickness ET1 of the first pixel electrode PE1 (e.g., in the third direction DR3) for allowing the light emitted by the first light-emitting diode ED1 to resonate, the thickness ET2 of the second pixel electrode PE2 (e.g., in the third direction DR3) for allowing the light emitted by the second light-emitting diode ED2 to resonate, and the thickness ET3 (e.g., in the third direction DR3) of the third pixel electrode PE3 for allowing the light emitted by the third light-emitting diode ED3 to resonate may be different from each other.

In an embodiment of the present disclosure, the thickness ET1 of the first pixel electrode PE1 (e.g., in the third direction DR3) may be adjusted to allow the light emitted by the first light-emitting diode ED1 to resonate, the thickness ET2 of the second pixel electrode PE2 (e.g., in the third direction DR3) may be adjusted to allow the light emitted by the second light-emitting diode ED2 to resonate, and the thickness ET3 of the third pixel electrode PE3 (e.g., in the third direction DR3) may be adjusted to allow the light emitted by the third light-emitting diode ED3 to resonate.

In an embodiment of the present disclosure, the thicknesses of the pixel electrodes PE1, PE2, PE3 (e.g., in the third direction DR3) may be adjusted to allow the light emitted by the corresponding light-emitting diodes ED1, ED2, ED3 to resonate, thereby increasing the device efficiency of the display device.

In an embodiment, the first to third pixel electrodes PE1, PE2, and PE3 may have different thicknesses (e.g., in the third direction DR3) from each other.

In an embodiment, the first inorganic layer IL1, the second inorganic layer IL2, and the fourth inorganic layer IL4 may have substantially the same thickness as each other (e.g., in the third direction DR3).

In an embodiment, the first hard mask layer HM1, the second hard mask layer HM2, and the third hard mask layer HM3 may be formed in substantially the same process step. In an embodiment, the first hard mask layer HM1, the second hard mask layer HM2, and the third hard mask layer HM3 may have substantially the same thickness as each other (e.g., in the third direction DR3).

In an embodiment, the first to third thicknesses T1, T2, T3 (e.g., in the third direction DR3) may be substantially the same as each other.

In an embodiment, the depth D1 of the first contact hole CNT1 (e.g., in the third direction DR3), the depth D2 of the first sub-contact hole SCNT1 (e.g., in the third direction DR3), and the depth D3 of the third sub-contact hole SCNT3 (e.g., in the third direction DR3) may be substantially the same as each other.

According to an embodiment of the present disclosure, a method for manufacturing the display device, which will be described later, may include forming first to third contact holes CNT1, CNT2, CNT3 for connecting the first to third upper metal layers UM1, UM2, UM3 to respective transistors TFT. This step may include a first etching step and a second etching step. In the first etching step, components disposed above the first to third intermediate hard masks MHM1, MHM2, MHM3 (see FIG. 16), which will be described later, may be etched. Once the first etching step is completed, second and fourth sub-contact holes SCNT2, SCNT4 may then be formed.

In the second etching step, the first to third contact holes CNT1, CNT2, CNT3 may be formed. The thicknesses of the components to be etched to form the first to third contact holes CNT1, CNT2, CNT3 in the second etching step may be substantially the same in the first to third preliminary pixel electrodes PPE1, PPE2, PPE3. Therefore, it is possible to prevent a damage to the first to third lower metal layers LM1, LM2, LM3 in the second etching step, thereby increasing the reliability of the display device.

The method for manufacturing the display device will be described later in greater detail.

In a comparative example, the display device does not include a contact hole within the pixel electrode. In such a comparative embodiment, the hard mask disposed within the pixel electrode serves as an etch stopper for forming an inorganic layer with a different thickness for each light-emitting diode. The hard mask is composed of multiple layers depending on the number of inorganic layers disposed within each pixel electrode.

According to an embodiment of the present disclosure, the first to third pixel electrodes PE1, PE2, PE3 may each include a single hard mask layer HM1, HM2, HM3. The first to third hard mask layers HM1, HM2, HM3 may have substantially the same thickness as each other (e.g., in the third direction DR3). The thicknesses of the components disposed beneath each of the first to third hard mask layers HM1, HM2, HM3 may be substantially the same as each other (e.g., in the third direction DR3) in the first to third pixel electrodes PE1, PE2, PE3.

According to an embodiment, the pixel defining layer PDL may be in direct contact with the first inorganic layer IL1 and the second inorganic layer IL2. In an embodiment of the present disclosure, the first upper metal layer UM1 may be electrically connected to the transistor TFT through the first contact hole CNT1 and may not cover an entirety of the first inorganic layer IL1. Similarly, the second upper metal layer UM2 may be electrically connected to the transistor TFT through the second contact hole CNT2 and may not cover an entirety of the second inorganic layer IL2. One side (e.g., a lateral end) of the first inorganic layer IL1 and one side (e.g., a lateral end) of the second inorganic layer IL2 may be exposed towards the pixel defining layer PDL, which is disposed between the first pixel electrode PE1 and the second pixel electrode PE2.

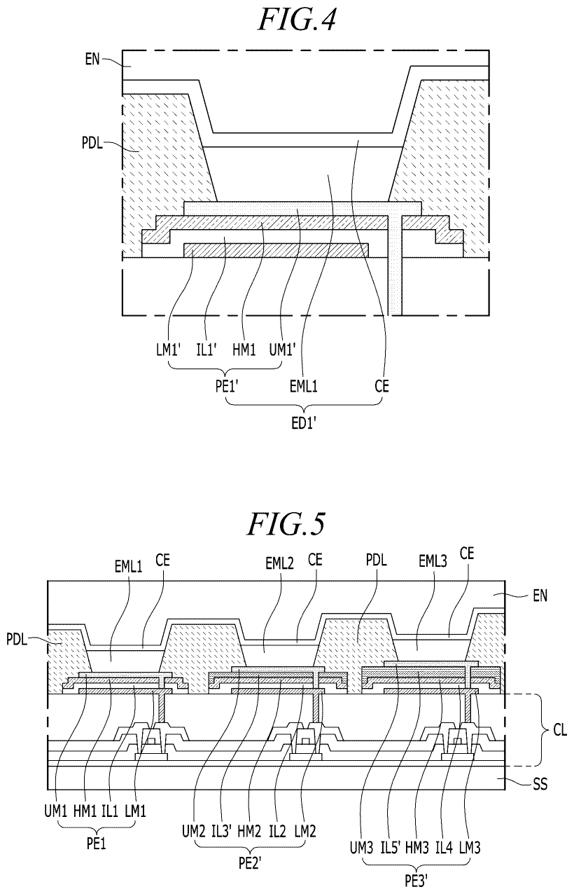

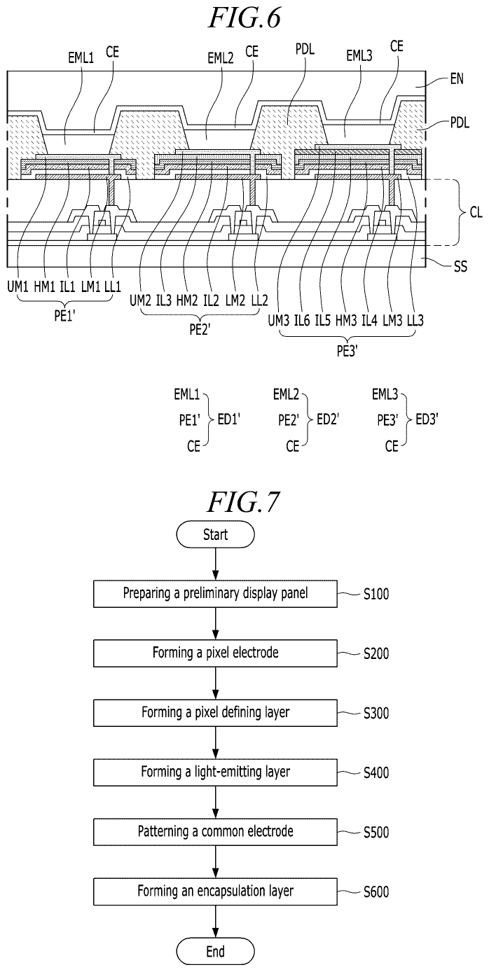

FIG. 4 is a cross-sectional view illustrating a portion of the display device according to an embodiment of the present disclosure. FIG. 5 is a cross-sectional view illustrating another portion of the display device according to an embodiment of the present disclosure. FIG. 6 is a cross-sectional view illustrating yet another portion of the display device according to an embodiment of the present disclosure.

Referring to FIG. 4, in an embodiment, a first lower metal layer LM1′ of a first pixel electrode PE1′ may be spaced apart (e.g., in the third direction DR3) and electrically insulated from a first upper metal layer UM1′. The first lower metal layer LM1′ may function as a reflective layer and may not be electrically connected to the transistor TFT (see FIG. 2), while the first upper metal layer UM1′ may be electrically connected to the transistor TFT. In an embodiment, the second light-emitting diode ED2 may have a similar configuration as the first light-emitting diode ED1′ shown in FIG. 4 in which the second lower metal layer LM2 may be spaced apart from the second contact hole CNT2 and the second upper metal layer UM2 may be electrically connected to a transistor TFT through the second contact hole CNT2.

Referring to FIG. 5, in an embodiment, a third inorganic layer IL3′ may have a thickness (e.g., in the third direction DR3) different from that of a fifth inorganic layer IL5′. A third pixel electrode PE3′ and a second pixel electrode PE2′ may have different thicknesses and different resonant distances from each other.

Referring to FIG. 6, in an embodiment the first pixel electrode PE1′ may further include a first lower inorganic layer LL1 disposed between the first lower metal layer LM1 and the first inorganic layer IL1 (e.g., in the third direction DR3). The second pixel electrode PE2′ may further include a second lower inorganic layer LL2 disposed between the second lower metal layer LM2 and the third inorganic layer IL3 (e.g., in the third direction DR3). The third pixel electrode PE3′ may further include a third lower inorganic layer LL3 disposed between the third lower metal layer LM3 and the fourth inorganic layer IL4 (e.g., in the third direction DR3). The first to third lower inorganic layers LL1, LL2, LL3 may have substantially the same thickness as each other (e.g., in the third direction DR3). In this embodiment, the first to third inorganic layers IL1, IL2, IL3 may be referred to as first to third upper inorganic layers, respectively.

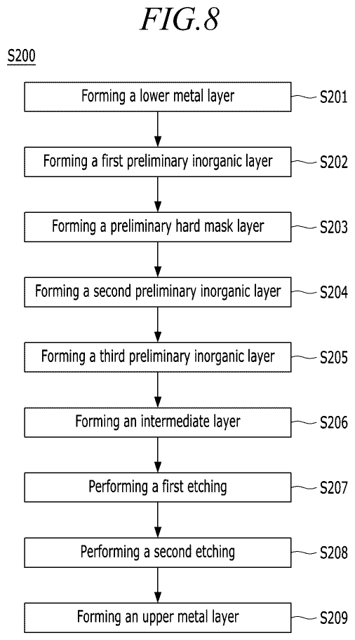

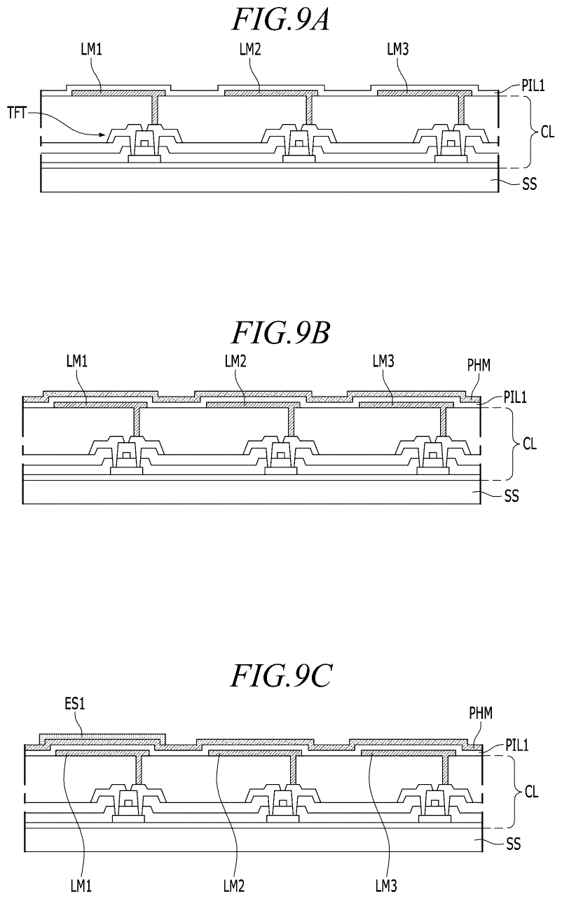

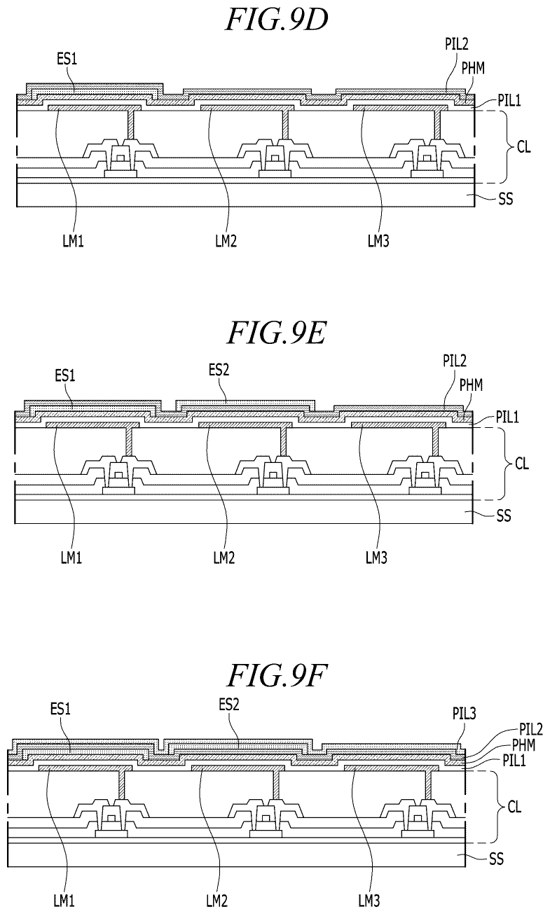

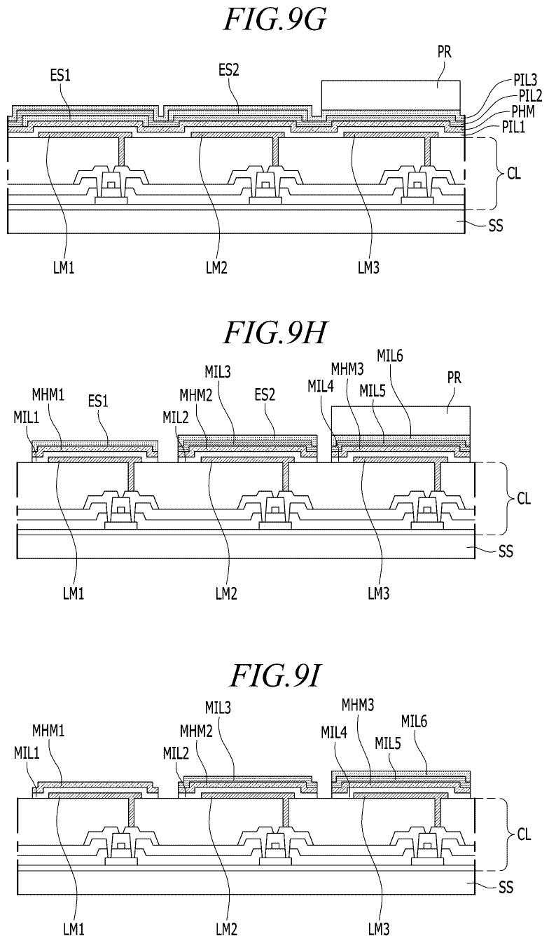

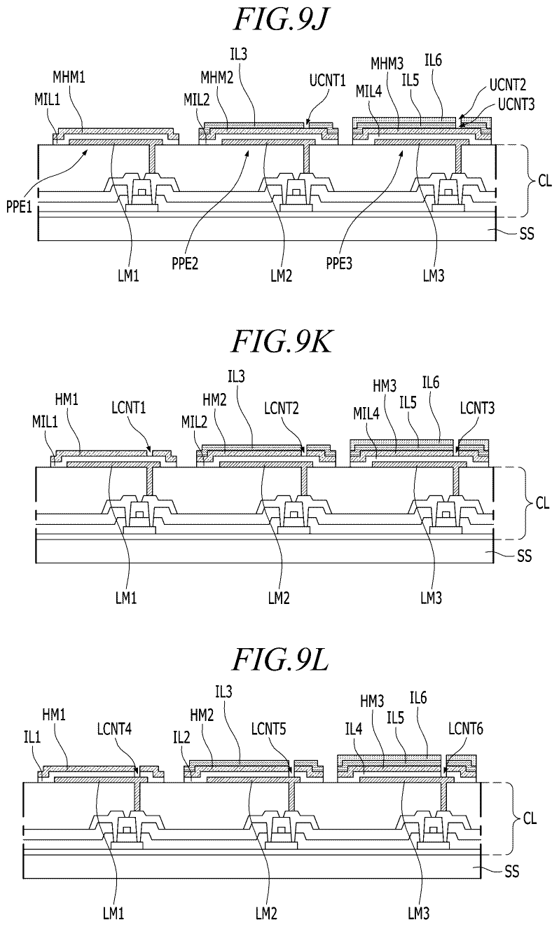

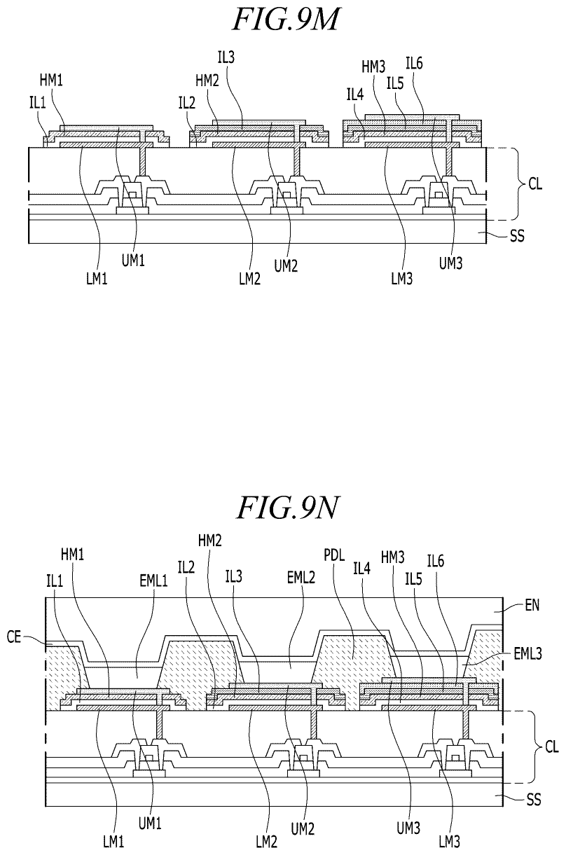

FIG. 7 is a flow diagram illustrating a method for manufacturing a display device according to an embodiment of the present disclosure. FIG. 8 is a flow diagram illustrating a particular step of the method for manufacturing a display device according to an embodiment of the present disclosure. FIGS. 9A to 9N are schematic views illustrating the steps of the method for manufacturing a display device according to embodiments of the present disclosure.

Referring to FIG. 7, the method for manufacturing a display device according to an embodiment of the present disclosure may include preparing a preliminary display panel in block S100, forming a pixel electrode in block S200, forming a pixel defining layer in block S300, forming a light-emitting layer in block S400, forming and patterning a common electrode in block S500, and forming an encapsulation layer in block S600.

Referring to FIG. 8, in an embodiment the step of forming a pixel electrode in block S200 may include forming a lower metal layer in block S201, forming a first preliminary inorganic layer in block S202, forming a preliminary hard mask layer in block S203, forming a second preliminary inorganic layer in block S204, forming a third preliminary inorganic layer in block S205, forming an intermediate layer in block S206, performing a first etching in block S207, performing a second etching in block S208, and forming an upper metal layer in block S209.

Referring to FIGS. 7, 8, and 9A, the step of preparing a preliminary display panel in block S100 may involve forming a circuit layer CL including a plurality of transistors TFT on a substrate SS. The step of forming a pixel electrode in block S200 may include forming lower Metal Layers LM1, LM2, LM3 on the Circuit Layer Cl in Block S201.

Referring to FIGS. 8 and 9B, the step of forming a first preliminary inorganic layer in block S202 may involve forming a first preliminary inorganic layer PIL1 on (e.g., directly thereon) the first to third lower metal layers LM1, LM2, LM3 and the circuit layer CL. The step of forming a preliminary hard mask layer in block S203 may involve forming a preliminary hard mask layer PHM on (e.g., directly thereon) the first preliminary inorganic layer PIL1.

Referring to FIGS. 8 and 9C, in an embodiment, the method for manufacturing a display device may further include forming a first etch stopper ES1 on (e.g., directly thereon) a region corresponding to the first pixel electrode PE1 (see FIG. 2) after forming the preliminary hard mask layer in block S203. The first etch stopper ES1 may be configured to prevent inorganic layers from remaining on the first intermediate hard mask layer MHM1 (see FIG. 9G) in the step of forming an intermediate layer in block S206, which will be described later.

Referring to FIGS. 8 and 9D, in the step of forming a second preliminary inorganic layer in block S204, a second preliminary inorganic layer PIL2 may be formed on (e.g., formed directly thereon) the preliminary hard mask layer.

Referring to FIGS. 8 and 9E, in an embodiment, the method for manufacturing a display device may further include forming a second etch stopper ES2 on (e.g., directly thereon) a region corresponding to the second pixel electrode PE2 (see FIG. 2) after forming the second preliminary inorganic layer in block S204. The second etch stopper ES2 may be configured to prevent inorganic layers from remaining on the second intermediate hard mask layer MHM2 (see FIG. 9G) during the step of forming an intermediate layer in block S206, which will be described later.

Referring to FIGS. 8 and 9F, in the step of forming a third preliminary inorganic layer in block S205, a third preliminary inorganic layer PIL3 may be formed on (e.g., formed directly thereon) the second preliminary inorganic layer PIL2.

Referring to FIGS. 8 and 9G, the step of forming an intermediate layer in block S206 may involve first forming a photoresist PR on a region corresponding to the third pixel electrode PE3 (see FIG. 2).

Referring to FIG. 9H, first through sixth intermediate inorganic layers MIL1, MIL2, MIL3, MIL4, MIL5, MIL6 and first through third intermediate hard mask layers MHM1, MHM2, MHM3 may be formed through an etching process.

Referring to FIG. 9I, the first etch stopper ES1, the second etch stopper ES2, and the photoresist PR may be removed.

Referring to FIGS. 8, 9I, and 9J, in the step of performing a first etching in block S207, portions of the inorganic films MIL3, MIL5, MIL6 disposed on the second and third intermediate hard mask layers MHM2 MHM3 may be removed to form upper contact holes UCNT1, UCNT2, UCNT3. For example, in an embodiment a portion of the third intermediate inorganic layer MIL3 located in the region corresponding to the second pixel electrode PE2 may be removed to form a first upper contact hole UCNT1 and form the third inorganic layer IL3. Additionally, in the step of performing a first etching in block S207, the sixth intermediate inorganic layer MIL6 located in the region corresponding to the third pixel electrode PE3 may be removed to form a second upper contact hole UCNT2, and the fifth intermediate inorganic layer MIL5 may be removed to form a third upper contact hole UCNT3, thereby forming the sixth inorganic layer IL6 and the fifth inorganic layer IL5.

In an embodiment of the present disclosure, the step of performing a first etching in block S207 may involve removing portions of the inorganic films MIL3, MIL5, MIL6 that have etching selectivity different from the intermediate hard mask layers MHM1, MHM2, MHM3 to prepare for the step of performing a second etching in block S208, which will be described later.

Referring to FIGS. 8, 9K, and 9L, in the step of performing a second etching in block S208, lower contact holes LCNT1, LCNT2, LCNT3 penetrating through the first to third hard mask layers HM1, HM2, HM3 may be formed first. The first to third hard mask layers HM1, HM2, HM3 may have substantially the same thickness as each other (e.g., in the third direction DR3), and the first to third lower contact holes LCNT1, LCNT2, LCNT3 may have substantially the same depth as each other (e.g., in the third direction DR3). Subsequently, fourth to sixth contact holes LCNT4, LCNT5, LCNT6 penetrating through the first inorganic layer IL1, the second inorganic layer IL2, and the fourth inorganic layer IL4, respectively, may be formed.

In an embodiment of the present disclosure, the first to third hard mask layers HM1, HM2, HM3 may include amorphous carbon (a-C), and the first inorganic layer IL1, the second inorganic layer IL2, and the fourth inorganic layer IL4 may include silicon oxide (SiOx).

In an embodiment, forming the first to third lower contact holes LCNT1, LCNT2, LCNT3 may be performed through oxygen ashing (e.g., O₂ ashing).

In an embodiment, forming the fourth to sixth lower contact holes LCNT4, LCNT5, LCNT6 may be performed through an etching process using fluorine-based dry gas.

Referring to FIGS. 8 and 9M, in the step of forming an upper metal layer in block S209, the first to third upper metal layers UM1, UM2, UM3 may be formed in regions, respectively, corresponding to the first to third pixel electrodes PE1, PE2, PE3 (see FIG. 2). The first upper metal layer UM1 may be electrically connected to the first lower metal layer LM1. The second upper metal layer UM2 may be electrically connected to the second lower metal layer LM2. The third upper metal layer UM3 may be electrically connected to the third lower metal layer LM3. However, as described above, embodiments of the present disclosure are not necessarily limited thereto, and in some embodiments, the first to third upper metal layers UM1, UM2, UM3 may be electrically insulated from the first to third lower metal layers LM1, LM2, LM3, respectively.

Referring to FIGS. 7 and 9N, in the step of forming a pixel defining layer in block S300, a pixel defining layer PDL may be formed between the first to third pixel electrodes PE1, PE2, PE3. In the step of forming a light-emitting layer in block S400, first to third light-emitting layers EML1, EML2, EML3 may be formed on the first to third pixel electrodes PE1, PE2, PE3, respectively. In the step of forming a common electrode in block S500, a common electrode CE may be formed on the pixel defining layer PDL and the light-emitting layers EML1, EML2, EML3. In the step of forming an encapsulation layer in block S600, an encapsulation layer EN may be formed on the common electrode CE.

With the method for manufacturing a display device according to an embodiment of the present disclosure, contact holes having the same depth as each other may be formed by arranging a single hard mask layer on inorganic layers having the same thickness as each other for each of the plurality of pixel electrodes. During this process, it is possible to prevent damage to the lower metal layers, thereby increasing the reliability of the display device. Additionally, since the pixel electrodes have different thicknesses, the light emitted from the light-emitting diodes included in the pixels may resonate, thereby increasing the device efficiency of the display device.

The display device according to an embodiment of the present disclosure may be applied to various electronic devices. An electronic device according to an embodiment may include the above-described display device and may further include modules or devices with additional functions beyond the display device.

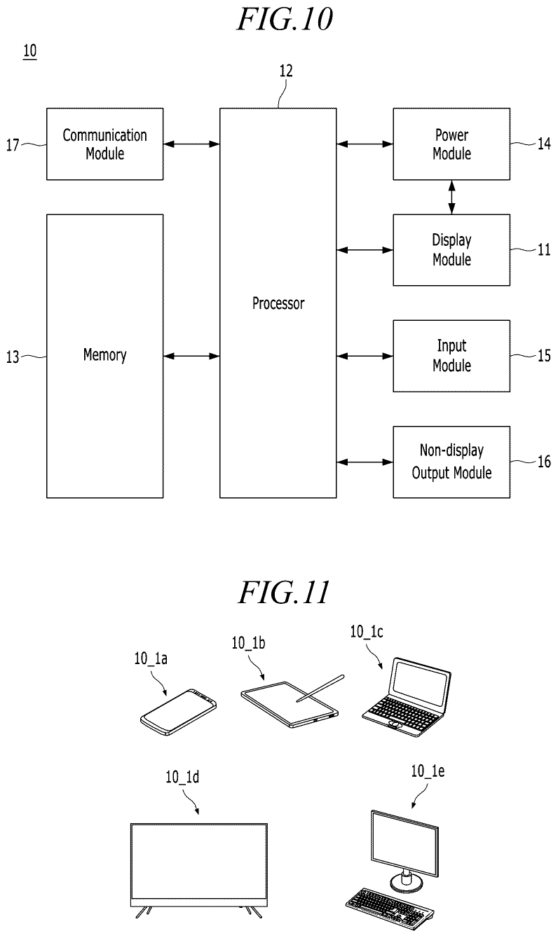

FIG. 10 is a block diagram of an electronic device according to an embodiment of the present disclosure. Referring to FIG. 10, an electronic device 10 according to an embodiment of the present disclosure may include a display module 11, a processor 12, a memory 13, and a power module 14. The electronic device 10 may further include an input module 15, a non-display output module 16, and/or a communication module 17.

The electronic device 10 may be configured to output various types of information in the form of images through the display module 11. When the processor 12 executes an application stored in the memory 13, the application may provide visual information to the user through the display module 11. The power module 14 may generate or supply power to the electronic device 10. The power module 14 may include a power supply module such as a power adapter or a battery device, as well as a power conversion module that is configured to convert the supplied power into a form required for the operation of the electronic device 10. The input module 15 may be configured to provide input information to the processor 12 and/or the display module 11. The non-display output module 16 may be configured to receive non-visual information, such as sound, haptic feedback, or illumination, from the processor 12 and provide it to the user. The communication module 17 may include a receiver and a transmitter configured to facilitate communication between the electronic device 10 and external devices.

At least one of the components of the electronic device 10 may be included within the display device described in the foregoing embodiments. Additionally, some of the individual modules functionally included within a single module may be integrated into the display device, while others may be provided separately from the display device. For example, the display device may include the display module 11, while the processor 12, memory 13, and power module 14 may be provided as separate components within the electronic device 10 rather than being integrated into the display device.

FIGS. 11 to 13 are schematic views of electronic devices according to various embodiments of the present disclosure. FIGS. 11 to 13 illustrate examples of various electronic devices in which the display device according to embodiments of the present disclosure may be applied.

FIG. 11 illustrates a smartphone 10_1a, a tablet PC 10_1b, a laptop 10_1c, a television (TV) 10_1d, and a desktop monitor 10_1e as examples of electronic devices.

The smartphone 10_1a may include the display module 11, as well as a communication module and an input module, such as, for example, a touch sensor. The smartphone 10_1a may be configured to process information received via the communication module or other input modules and display the information through the display module of the display device.

The tablet PC 10_1b, the laptop 10_1c, the TV 10_1d, and the desktop monitor 10_1e may also include the display module and an input module, similarly to the smartphone 10_1a, and, in some cases, may further include a communication module.

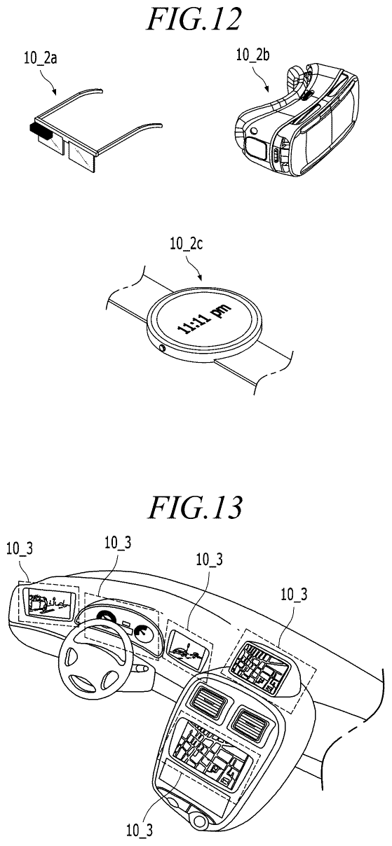

FIG. 12 illustrates examples where an electronic device including a display module is applied to wearable electronic devices. Examples of such wearable electronic devices may include smart glasses 10_2a, a head-mounted display 10_2b, and a smartwatch 10_2c. However, embodiments of the present disclosure are not necessarily limited thereto and the electronic device may be various different small-sized, medium-sized or large-sized electronic devices.

The smart glasses 10_2a and the head-mounted display 10_2b may include a display module, which is configured to output an image, as well as a reflector configured to reflect the displayed image toward the user's eyes. Through these components, these wearable electronic devices are able provide virtual reality or augmented reality visuals to the user.

The smartwatch 10_2c may include a biometric sensor as an input device and may be configured to display biometric information detected by the sensor through the display module.

FIG. 13 illustrates an example where an electronic device including a display module is adopted in a vehicle. For example, the electronic device 10_3 may be applied to the instrument panel, center console, or dashboard display of a vehicle. It may also be applied to a center information display (CID) mounted on the dashboard or to a room mirror display that replaces traditional side-view mirrors.

Hitherto, certain non-limiting embodiments of the present disclosure have been described above, but these are merely examples and are not intended to limit embodiments of the present disclosure. Those skilled in the art to which the present disclosure pertains may make various modifications and changes to the described embodiments by adding, changing, deleting, or adding certain elements, without departing from the scope of the technical ideas of the present disclosure, and such modifications and changes should also be regarded as being within the scope of the present disclosure.

What is claimed is:

1. A display device comprising:
a substrate having a plurality of light-emitting regions defined therein;
a circuit layer disposed on the substrate, the circuit layer comprising a plurality of transistors; and
a first light-emitting diode and a second light-emitting diode disposed on the circuit layer,
wherein the first light-emitting diode overlaps a first light-emitting region among the plurality of light-emitting regions and comprises a first pixel electrode, a first light-emitting layer, and a common electrode,
wherein the second light-emitting diode overlaps a second light-emitting region among the plurality of light-emitting regions and comprises a second pixel electrode, a second light-emitting layer, and the common electrode,
wherein the first pixel electrode comprises, in sequential stacking order, a first lower metal layer, a first inorganic layer, a first hard mask layer, and a first upper metal layer and has a first contact hole defined therein, the first contact hole penetrating through the first inorganic layer and the first hard mask layer,
wherein the second pixel electrode comprises, in sequential stacking order, a second lower metal layer, a second inorganic layer, a second hard mask layer, a third inorganic layer, and a second upper metal layer and has a second contact hole defined therein, the second contact hole penetrating through the second inorganic layer, the second hard mask layer, and the third inorganic layer,
wherein the first inorganic layer and the second inorganic layer have substantially a same thickness as each other in a vertical direction, and
wherein the first pixel electrode and the second pixel electrode have different thicknesses from each other in the vertical direction.

2. The display device of claim 1, wherein the thickness of the second pixel electrode in the vertical direction is greater than the thickness of the first pixel electrode in the vertical direction.

3. The display device of claim 1, wherein the first hard mask layer and the second hard mask layer have substantially a same thickness as each other in the vertical direction.

4. The display device of claim 1, wherein each of the first hard mask layer and the second hard mask layer has an etching selectivity different from that of the third inorganic layer.

5. The display device of claim 1, wherein the second contact hole comprises:
a first sub-contact hole penetrating through the second inorganic layer and the second hard mask layer; and
a second sub-contact hole penetrating through the third inorganic layer,
wherein the first contact hole and the first sub-contact hole have substantially a same depth as each other.

6. The display device of claim 1, further comprising a third light-emitting diode disposed on the circuit layer,
wherein the third light-emitting diode overlaps a third light-emitting region among the plurality of light-emitting regions,
wherein the third light-emitting diode comprises a third pixel electrode, a third light-emitting layer, and the common electrode,
wherein the third pixel electrode comprises, in sequential stacking order, a third lower metal layer, a fourth inorganic layer, a third hard mask layer, a fifth inorganic layer, a sixth inorganic layer, and a third upper metal layer,
wherein the third pixel electrode includes a third contact hole penetrating through the fourth inorganic layer, the third hard mask layer, the fifth inorganic layer, and the sixth inorganic layer, and
wherein the fourth inorganic layer, the first inorganic layer, and the second inorganic layer have substantially a same thickness as each other in the vertical direction.

7. The display device of claim 6, wherein the first hard mask layer, the second hard mask layer, and the third hard mask layer have substantially a same thickness as each other in the vertical direction.

8. The display device of claim 6, wherein the second contact hole comprises:
a first sub-contact hole penetrating through the second inorganic layer and the second hard mask layer; and
a second sub-contact hole penetrating through the third inorganic layer,
wherein the third contact hole comprises:
a third sub-contact hole penetrating through the fourth inorganic layer and the third hard mask layer; and
a fourth sub-contact hole penetrating through the fifth inorganic layer and the sixth inorganic layer,
wherein the third sub-contact hole, the first contact hole, and the first sub-contact hole have substantially a same depth as each other.

9. The display device of claim 1, wherein the first lower metal layer is spaced apart from the first contact hole,
wherein the second lower metal layer is spaced apart from the second contact hole,
wherein the first upper metal layer is electrically connected to a corresponding transistor among the plurality of transistors through the first contact hole, and
wherein the second upper metal layer is electrically connected to a corresponding transistor among the plurality of transistors through the second contact hole.

10. The display device of claim 1, further comprising a pixel defining layer disposed between the first pixel electrode and the second pixel electrode,
wherein the pixel defining layer is in direct contact with the first inorganic layer and the second inorganic layer.

11. The display device of claim 1, wherein each of the first hard mask layer and the second hard mask layer comprises amorphous carbon (a-C).

12. The display device of claim 1, wherein the third inorganic layer comprises silicon oxide (SiOx).

13. A method for manufacturing a display device, the method comprising:
preparing a preliminary display panel by forming a circuit layer on a substrate;
forming a plurality of lower metal layers spaced apart from each other on the circuit layer;
forming an intermediate layer by: forming a first intermediate inorganic layer and a first intermediate hard mask layer on a first lower metal layer among the plurality of lower metal layers; and forming a second intermediate inorganic layer, a second intermediate hard mask layer, and a third intermediate inorganic layer on a second lower metal layer among the plurality of lower metal layers;
performing a first etching to form a first upper contact hole penetrating through the third intermediate inorganic layer;
performing a second etching to form a first lower contact hole penetrating through the first intermediate hard mask layer and the first intermediate inorganic layer and form a second lower contact hole penetrating through the second intermediate hard mask layer and the second intermediate inorganic layer and overlapping the first upper contact hole in a plan view; and
forming upper metal layers corresponding, respectively, to the plurality of lower metal layers.

14. The method of claim 13, wherein, in the step of forming an intermediate layer, a fourth intermediate inorganic layer, a third intermediate hard mask layer, a fifth intermediate inorganic layer, and a sixth intermediate inorganic layer are further formed on a third lower metal layer among the plurality of lower metal layers,
wherein, in the step of performing a first etching, a second upper contact hole penetrating through the sixth intermediate inorganic layer and a third upper contact hole penetrating through the fifth intermediate inorganic layer are further formed, and
wherein in the step of performing a second etching, a third lower contact hole penetrating through the third intermediate hard mask layer is further formed.

15. The method of claim 14, wherein the first to third intermediate hard mask layers have an etching selectivity different from that of the third intermediate inorganic layer.

16. The method of claim 14, wherein the first to third intermediate hard mask layers comprise amorphous carbon (a-C).

17. The method of claim 14, wherein the third inorganic layer comprises silicon oxide (SiOx).

18. An electronic device comprising a display device, the display device comprising:
a processor controlling a display device;
a memory storing data required for operating the display device or the processor; and
a power conversion module generating or supplying power,
wherein the display device comprises:
a substrate having a plurality of light-emitting regions defined therein;
a circuit layer disposed on the substrate, the circuit layer comprising a plurality of transistors; and
a first light-emitting diode and a second light-emitting diode disposed on the circuit layer,
wherein the first light-emitting diode overlaps a first light-emitting region among the plurality of light-emitting regions and comprises a first pixel electrode, a first light-emitting layer, and a common electrode,
wherein the second light-emitting diode overlaps a second light-emitting region among the plurality of light-emitting regions and comprises a second pixel electrode, a second light-emitting layer, and the common electrode,
wherein the first pixel electrode comprises, in sequential stacking order, a first lower metal layer, a first inorganic layer, a first hard mask layer, and a first upper metal layer and has a first contact hole defined therein, the first contact hole penetrating through the first inorganic layer and the first hard mask layer,
wherein the second pixel electrode comprises, in sequential stacking order, a second lower metal layer, a second inorganic layer, a second hard mask layer, a third inorganic layer, and a second upper metal layer and has a second contact hole defined therein, the second contact hole penetrating through the second inorganic layer, the second hard mask layer, and the third inorganic layer,
wherein the first inorganic layer and the second inorganic layer have substantially a same thickness as each other in a vertical direction, and
wherein the first pixel electrode and the second pixel electrode have different thicknesses from each other in the vertical direction.

19. The electronic device of claim 18, wherein the thickness of the second pixel electrode in the vertical direction is greater than the thickness of the first pixel electrode in the vertical direction.

20. The electronic device of claim 18, wherein each of the first hard mask layer and the second hard mask layer comprises amorphous carbon (a-C).
